(19) United States
(12) Patent Application Publication
(10) Pub. No.: US 2016/0005930 A1
(43) Pub. Date: Jan. 7, 2016

(54) OPTOELECTRONIC SEMICONDUCTOR CHIP ENCAPSULATED WITH AN ALD LAYER AND CORRESPONDING METHOD OF PRODUCTION

(71) Applicant: OSRAM OPTO SEMICONDUCTORS GMBH, Regensburg (DE)

(72) Inventors: Karl Engl, Pentling (DE); Georg Hartung, Nesselwang (DE); Markus Maute, Alteglofsheim (DE)

(73) Assignee: OSRAM OPTO SEMICONDUCTORS GMBH, Regensburg (DE)

(21) Appl. No.: 14/769,125

(22) PCT Filed: Mar. 14, 2014
(86) PCT No.: PCT/EP2014/055110

§ 371 Date: Aug. 20, 2015

(30) Foreign Application Priority Data
Mar. 26, 2013 (DE) 10 2013 103 079.3

(51) Int. Cl. H01L 33/46; H01L 33/38; H01L 33/54

(52) U.S. Cl. CPC H01L 33/46; H01L 33/54; H01L 33/382; H01L 2933/0025; H01L 2933/005

(57) ABSTRACT

An optoelectronic semiconductor chip includes a semiconductor body including n-conducting and p-conducting regions, an active region generating electromagnetic radiation, a mirror layer reflecting the electromagnetic radiation, and an encapsulating layer sequence formed with an insulating material, wherein the mirror layer is arranged at an underside of the p-conducting region, the active region is arranged at a side of the p-conducting region facing away from the mirror layer, the n-conducting region is arranged at a side of the active region facing away from the p-conducting region, the encapsulation layer sequence covers the semiconductor body at the outer surface thereof in places, the encapsulation layer sequence extends at the outer surface of the semiconductor body from the active region along the p-conducting region as far as below the mirror layer, and the encapsulation layer sequence includes at least one encapsulation layer which is an ALD layer or consists of an ALD layer.

### TECHNICAL FIELD

This disclosure relates to an optoelectronic semiconductor chip and a method of producing an optoelectronic semiconductor chip.

### BACKGROUND

WO 2012/171817 describes an optoelectronic semiconductor chip. However, it could be helpful to provide an optoelectronic semiconductor chip having an improved small-current behavior and a lengthened lifetime.

### SUMMARY

We provide an optoelectronic semiconductor chip including a semiconductor body including an n-conducting region, an active region that generates electromagnetic radiation, and a p-conducting region; a first mirror layer that reflects the electromagnetic radiation; and an encapsulation layer sequence formed with an electrically insulating material, wherein the first mirror layer is arranged at an underside of the p-conducting region; the active region is arranged at a side of the p-conducting region facing away from the first mirror layer; the n-conducting region is arranged at a side of the active region facing away from the p-conducting region; the encapsulation layer sequence covers the semiconductor body at the outer surface thereof in places; the encapsulation layer sequence extends at the outer surface of the semiconductor body from the active region along the p-conducting region as far as below the first mirror layer; and the encapsulation layer sequence includes at least one encapsulation layer which is an ALD layer or consists of an ALD layer.

We also provide a method of producing the optoelectronic semiconductor chip including a semiconductor body including an n-conducting region, an active region that generates electromagnetic radiation, and a p-conducting region; a first mirror layer that reflects the electro-magnetic radiation; and an encapsulation layer sequence formed with an electrically insulating material, wherein the first mirror layer is arranged at an underside of the p-conducting region; the active region is arranged at a side of the p-conducting region facing away from the first mirror layer; the n-conducting region is arranged at a side of the active region facing away from the p-conducting region; the encapsulation layer sequence covers the semiconductor body at the outer surface thereof in places; the encapsulation layer sequence extends at the outer surface of the semiconductor body from the active region along the p-conducting region as far as below the first mirror layer; and the encapsulation layer sequence includes at least one encapsulation layer which is an ALD layer or consists of an ALD layer, including providing a growth substrate; applying the semiconductor body to the growth substrate, wherein the n-conducting region faces the growth substrate and the p-conducting region faces away from the growth substrate; removing the p-conducting region and the active region in places and exposing the n-conducting region in places; applying the encapsulation layer sequence on exposed outer surfaces of the p-conducting region, of the active region and of the n-conducting region; removing the encapsulation layer sequence in places at an underside of the p-conducting region facing away from the n-conducting region, and exposing the p-conducting region in places; and arranging the first mirror layer on the exposed places of the p-conducting region, wherein applying the encapsulation layer sequence is carried out temporally before arranging the first mirror layer.

We further provide an optoelectronic semiconductor chip including a semiconductor body including an n-conducting region, an active region that generates electromagnetic radiation, and a p-conducting region; a first mirror layer that reflects the electromagnetic radiation; and an encapsulation layer sequence formed with an electrically insulting material, wherein the first mirror layer is arranged at an underside of the p-conducting region; the active region is arranged at a side of the p-conducting region facing away from the first mirror layer; the n-conducting region is arranged at a side of the active region facing away from the p-conducting region; the encapsulation layer sequence covers the semiconductor body at outer surface thereof in places; the encapsulating layer sequence extends at the outer surface of the semiconductor body from the active region along the p-conducting region as far as below the first mirror layer; the encapsulation layer sequence includes at least one encapsulation layer which is an ALD layer or consists of an ALD layer; the encapsulation layer sequence is situated partly in the n-conducting region at the outer surface of the semiconductor body and extends along the underside of the first mirror layer facing away from the p-conducting region; and the encapsulation layer sequence covers the first mirror layer at least in places.

We further also provide a method of producing an optoelectronic semiconductor chip including providing a growth substrate; applying a semiconductor body to the growth substrate, wherein a n-conducting region of the semiconductor body faces the growth substrate and a p-conducting region of the semiconductor body faces away from the growth substrate; removing the p-conducting region and an active region of the semiconductor body in places and exposing the n-conducting region in places; applying an encapsulation layer sequence on exposed outer surfaces of the p-conducting region of the active region and of the n-conducting region; removing the encapsulation layer sequence in places at an underside of the p-conducting region facing away from the n-conducting region, and in the process exposing the p-conducting region in places; arranging a first mirror layer on the exposed places of the p-conducting region, wherein applying the encapsulation layer sequence is carried out temporally before arranging the first mirror layer; and the encapsulation layer sequence includes at least one encapsulation layer which is an ALD layer or consists of an ALD layer and which is deposited at least in places using ozone as a precursor.

### BRIEF DESCRIPTION OF THE DRAWINGS

FIGS. 1A to 1Q show method steps for one example of a method of producing an optoelectronic semiconductor chip.

FIGS. 1Q, 2, 3 and 4 show schematic sectional illustrations concerning examples of optoelectronic semiconductor chips.

### LIST OF REFERENCE SIGNS

1 growth substrate
2 n-conducting region of the semiconductor body
3 p-conducting region of the semiconductor body
4 active region
10 semiconductor body
11 first encapsulation layer (dual layer 1)
12 second encapsulation layer (ALD layer)
13 third encapsulation layer (dual layer 2)
14 fourth encapsulation layer (ALD layer)
15 fifth encapsulation layer (SiO₂)
16 contact point between second and fourth encapsulation layers
17 sixth encapsulation layer
20 encapsulation layer sequence
21 first mirror layer
22 second mirror layer
31 p-type connection layer
40 plated-through hole
41 n-type contact material
42 metallic encapsulation layer
43 contact region
50 carrier body
51 rear-side metallization
60 mask layer

### DETAILED DESCRIPTION

Our optoelectronic semiconductor chip may comprise a semiconductor body. The semiconductor body is, in particular, a semiconductor body grown epitaxially. The semiconductor body comprises an n-conducting region, an active region that generates electromagnetic radiation, and a p-conducting region.

In the active region of the semiconductor body, electromagnetic radiation in the spectral range between UV radiation and infrared radiation, in particular in the spectral range of visible light is generated, for example, during operation. For this purpose, the semiconductor body is based, for example, on a III-V semiconductor material, for example, on a nitride compound semiconductor material.

The electromagnetic radiation generated in the active region is generated by energization of the active region. The electromagnetic radiation generated in this way leaves the semi-conductor body at least partly via the outer surface thereof.

The optoelectronic semiconductor chip may comprise a first mirror layer that reflects the electromagnetic radiation generated in the active region. The first mirror layer is arranged, for example, at a first main surface of the semiconductor body. A large part of the electromagnetic radiation generated in the active region during operation then leaves the optoelectronic semiconductor chip through a second main surface opposite the first main surface. In this case, electromagnetic radiation generated in the active region of the semiconductor body impinges partly on the first mirror layer and is reflected by the latter in the direction of the outer surface of the semiconductor body, in particular in the direction of the second main surface, where it then partly emerges.

The mirror layer is, in particular, metallic. By way of example, the mirror layer contains or consists of one of the following metals: silver, aluminum. These metals have a good to very good reflectivity for visible light, but can have the disadvantage that they tend toward diffusion or electromigration particularly if, case during operation of the optoelectronic semiconductor chip, an electromagnetic field is present. Furthermore, the metals can oxidize particularly in a moist environment, which reduces reflectivity and thus efficiency of the semiconductor body to a greater and greater extent as the operational duration increases.

The optoelectronic semiconductor chip may comprise an encapsulation layer sequence. The encapsulation layer sequence is formed with at least one electrically insulating material and is in particular electrically insulating. The encapsulation layer sequence comprises at least one encapsulation layer, in particular a plurality of encapsulation layers. The individual encapsulation layers of the encapsulation layer sequence can be produced by different production methods. The encapsulation layer sequence in particular prevents diffusion of material from the first mirror layer into other regions of the optoelectronic semiconductor chip and/or impedes or prevents penetration of atmospheric gases or moisture to the first mirror layer.

The first mirror layer may be arranged at an underside of the p-conducting region. The underside of the p-conducting region is, for example, the side of the semiconductor body facing away from the n-conducting region. In this case, the mirror layer can be in direct contact with the p-conducting region. The first mirror layer then in particular also impresses electric current into the p-conducting region during operation of the optoelectronic semiconductor chip.

The active region may be arranged at a side of the p-conducting facing away side of the p-conducting region facing away from the first mirror layer, and the n-conducting region is arranged at a p-conducting facing away side of the active region. That is to say that the active region is arranged between p-conducting region and n-conducting region, wherein the first mirror layer is arranged at the underside of the p-conducting region facing away from the n-conducting region.

The encapsulation layer sequence may cover the semiconductor body at the outer surface thereof in places. That is to say that the encapsulation layer sequence extends in places along the outer surface of the semiconductor body and can be in direct contact with the semiconductor body at least in regions. That is to say that the encapsulation layer sequence is then applied directly to the semiconductor body in places.

The encapsulation layer sequence may extend at the outer surface of the semiconductor body from the active region along the p-conducting region as far as below the first mirror layer. In this case, the encapsulation layer sequence is arranged in particular at the p/n junction of the semiconductor body, that is to say in the region of the active region, at the outer surface of the semiconductor body. In this case, it is possible for the encapsulation layer sequence to completely cover the active region at the outer surface of the semiconductor body. That is to say that the entire p/n junction of the semiconductor body is covered by the encapsulation layer sequence. The encapsulation layer sequence then completely surrounds the semiconductor body at least at the active region in the manner of a frame or a ring. In this case, the encapsulation layer sequence can also be situated partly in the n-conducting region at the outer surface of the semiconductor body. The encapsulation layer sequence extends from the active region along the p-conducting region to a level as far as below the first mirror layer. As a result, it is possible, for example, for the semiconductor body to be completely covered by the encapsulation layer sequence in the p-conducting region at its side surface. In this case, the side surface is that surface of the semiconductor body which runs perpendicularly or transversely with respect to the main surfaces, wherein one of the main surfaces is formed by the underside of the p-conducting region, at which the first mirror layer is situated.

The encapsulation layer sequence can then extend as far as below the first mirror layer and in this case also the side surface of the mirror layer adjacent to the side surface of the semiconductor body, in particular the side surface in the p-conducting region of the semiconductor body. In this case, the encapsulation layer sequence need not run below the first mirror layer. It is sufficient if the encapsulation layer sequence extends far enough that it is arranged at a distance from the mirror layer in places in the vertical direction, that is to say extends to a level as far as below the first mirror layer. In this case, the vertical direction is a direction running transversely or perpendicular with respect to the main extension direction of the semiconductor body.

The encapsulation layer sequence may comprise at least one encapsulation layer which is an ALD (atomic layer deposition) layer or consists of an ALD layer. That is to say that at least this encapsulation layer of the encapsulation layer sequence is formed by an ALD method. Very thin layers having a polycrystalline or amorphous structure can be produced by an ALD method. Since a layer produced by ALD grows proportionally to the number of reaction cycles with which the layer is produced, exact control of the layer thickness is possible. Particularly uniform layers, that is to say layers having a particularly uniform thickness, can be produced by the ALD method. Furthermore, very dense layers having few crystal defects are obtained as a result of the monolayer growth using the ALD method.

In other words, at least one encapsulation layer of the encapsulation layer sequence is deposited with the aid of an ALD process such as flash ALD, photoinduced ALD or some other ALD method. In this case, a high-temperature ALD method can also be used, in particular, in which the encapsulation layer is deposited at temperatures of 100° C. or more.

An encapsulation layer produced by an ALD method is clearly distinguishable from layers produced by alternative methods such as conventional CVD (chemical vapor deposition), for example, by electromicroscopic examinations and other analysis methods of semiconductor technology. The feature according to which the encapsulation layer is an ALD layer is therefore a substantive feature that is demonstrable on the finished optoelectronic semiconductor chip.

The encapsulation layer which is an ALD layer is formed with an electrically insulating material and has, for example, a thickness of 0.05 nm to at most 500 nm, in particular at least 30 nm to at most 50 nm, for example, a thickness of 40 nm. In this case, the encapsulation layer can comprise a multiplicity of sublayers arranged one on top of another. The encapsulation layer contains or consists, for example, of one of the following materials: Al₂O₃, SiO₂, SiN. In this case, it is also possible, in particular, for the encapsulation layer which is an ALD layer to contain a combination of these materials.

The semiconductor chip may comprise a semiconductor body comprising an n-conducting region, an active region that generates electromagnetic radiation, and a p-conducting region. The semiconductor chip furthermore comprises a first mirror layer that reflects the electromagnetic radiation, and an encapsulation layer sequence formed with an electrically insulating material. In this case, the first mirror layer is arranged at an underside of the p-conducting region, the active region is arranged at a side of the p-conducting region facing away from the first mirror layer, and the n-conducting region is arranged at a side of the active region facing away from the p-conducting region. The encapsulation layer sequence covers the semiconductor body at the outer surface thereof in places. The encapsulation layer sequence extends at the outer surface of the semiconductor body from the active region along the p-conducting region as far as below the first mirror layer, and the encapsulation layer sequence comprises at least one encapsulation layer which is an ALD layer or which consists of an ALD layer.

In this case, an optoelectronic semiconductor chip described here is based, inter alia, on the following considerations. Optoelectronic semiconductor chips, in particular light emitting diode chips, for a long durability and thus a long lifetime, have to be reliably protected against the action of moisture from the environment. The optoelectronic semiconductor chips generally consist of different materials. Materials such as silver or aluminum having a low resistance to moisture are used in particular to form the first mirror layer. One possibility of protecting the first mirror layer is metallically encapsulating the mirror layer, that is to say, for example, with a metal layer. However, materials appropriate for this purpose absorb a high proportion of the electromagnetic radiation generated during operation and therefore lead to a reduced efficiency of the optoelectronic semiconductor chip.

In the optoelectronic semiconductor chip described here, an encapsulation layer sequence formed with an electrically insulating material and comprising at least one encapsulation layer produced by an ALD method is used to encapsulate the first mirror layer. Such an encapsulation layer proves to be particularly advantageous since it reliably protects against moisture and at the same time has hardly any or no absorbent properties.

Furthermore, the encapsulation layer in accordance with an optoelectronic semiconductor chip described here is not only used to encapsulate the first mirror layer, but it also covers the p/n junction of the semiconductor body on the outer surface of the semiconductor body. We found that such “burying” of the p/n junction or of the active region greatly improves the small-current behavior of the optoelectronic semiconductor chip such that electromagnetic radiation can be generated with high efficiency even at very low current intensities of 1 μA. The in particular non-metallic encapsulation layer sequence thus leads to an increase in brightness compared to an optoelectronic semiconductor chip in which the mirror layer is metallically encapsulated, to an improved aging behavior and to an improved small-current behavior.

The encapsulation layer sequence may extend along the underside of the first mirror layer facing away from the p-conducting region, wherein the encapsulation layer sequence completely covers the first mirror layer. That is to say that the encapsulation layer sequence may not only be led as far as below the first mirror layer, but the encapsulation layer sequence may run further below the mirror layer such that the entire first mirror layer is covered by the encapsulation layer sequence.

In this case, “covered” does not mean that the encapsulation layer sequence must be in direct contact with the first mirror layer at the underside thereof. Rather, it is also possible for a p-type connection metal to be arranged between the encapsulation layer sequence and the first mirror layer at least in places. Furthermore, it is possible that not all the layers of the encapsulation layer sequence extend below the first mirror layer, rather some partial layers of the encapsulation layer sequence are not led under the first mirror layer.

Furthermore, it is possible, in particular, for the encapsulation layer sequence, or partial layers of the encapsulation layer sequence, apart from regions in which at least one plated-through hole for contacting the n-conducting region is arranged, to cover the entire cross section of the optoelectronic semiconductor chip.

Overall, an encapsulation layer sequence extending along the underside of the first mirror layer facing away from the p-conducting region enables a particularly good encapsulation of the first mirror layer.

The semiconductor chip may comprise at least one further encapsulation layer which is an ALD layer, wherein the further encapsulation layer completely covers the outer surface of the semiconductor body at least at the n-conducting region of the semiconductor body. In this case, the semiconductor body can be completely covered by the further encapsulation layer at its non-covered regions, which would be exposed without the further encapsulation layer. In this case, the further encapsulation layer can be, for example, identical to the encapsulation layer which is part of the encapsulation layer sequence.

In this case, the encapsulation layer and the further encapsulation layer can be in direct contact with one another at at least one contact point. That is to say that at locations at which the encapsulation layer of the encapsulation layer sequence is exposed, that is to say where it is not covered by further layers, the encapsulation layer can be in direct contact with the further encapsulation layer. In this way, contact points (hereinafter also called: triple points) form at which ALD layers directly adjoin one another. As a result, it is possible, for example, for the semiconductor body to be enclosed as fully as possible by encapsulation layers produced by an ALD method.

The optoelectronic semiconductor chip may comprise at least one plated-through hole which extends through the p-conducting region and the active region well into the n-conducting region, wherein the plated-through hole comprises an in particular metallic n-type contact material via which the n-conducting region is electrically contactable, and the semiconductor body, apart from the at least one plated-through hole, is completely enclosed by the encapsulation layers which are ALD layers. In this case, the at least one plated-through hole can penetrate through the encapsulation layer sequence or partial layers of the encapsulation layer sequence, the first mirror layer, the p-conducting region of the semiconductor body and the active region. In this case, it is possible for the optoelectronic semiconductor chip to comprise a multiplicity of plated-through holes of identical type.

The plated-through hole comprises, for example, a cutout in the semiconductor body filled with the n-type contact material, for example, a metal. The n-type contact material directly contacts the n-conducting region and imparts an electrically conductive connection, for example, to a connection location of the optoelectronic semiconductor chip which is contactable from outside the semiconductor chip.

In this case, it is possible for the encapsulation layer sequence, or partial layers of the encapsulation layer sequence, to directly adjoin the n-type contact material in places. For this purpose, the encapsulation layer sequence can likewise be formed, for example, within the plated-through hole. That is to say that the encapsulation layer sequence also serves to electrically insulate the n-type contact material, for example, from the first mirror layer, the p-conducting region of the semiconductor body and the active region.

The optoelectronic semiconductor chip may comprise a second mirror layer, which is arranged at the underside of the n-type contact material facing away from the n-conducting region, wherein the encapsulation layer sequence is arranged in places between the first mirror layer and the second mirror layer. The second mirror layer can be formed with the same material as the first mirror layer. The second mirror layer makes otherwise light-absorbing regions of the optoelectronic semiconductor chip more reflective and thus further increases efficiency of the optoelectronic semiconductor chip. The second mirror layer is arranged below the n-type contact material and reflects electromagnetic radiation which impinges in the region of the plated-through hole. The second mirror layer can electrically conductively connect to the n-type contact material and in particular directly contacts the n-type contact material. That is to say that the second mirror layer electrically conductively connects, for example, to the n-conducting region of the semiconductor body.

The encapsulation layer sequence or partial layers of the encapsulation layer sequence can be situated at least indirectly between the first mirror layer and the second mirror layer. In this way, the encapsulation layer sequence or parts of the encapsulation layer sequence can constitute an electrical insulation between the first mirror layer and the second mirror layer. If the second mirror layer electrically conductively connects, for example, to the n-conducting region of the semiconductor body, then the first mirror layer electrically conductively connects to the p-conducting region of the semiconductor body.

The second mirror layer may project beyond the outer surface of the semiconductor body in a lateral direction. In this case, the encapsulation layer sequence can run at least in places at the side of the second mirror layer facing the semiconductor body. The second mirror layer reflects electromagnetic radiation generated by the semiconductor body during operation. The second mirror layer can be formed with the same materials as the first mirror layer.

The second mirror layer projects beyond the semiconductor body in a lateral direction running parallel to the main extension plane of the semiconductor body. The second mirror layer therefore projects laterally beyond the semiconductor body. In this way, the second mirror layer can also reflect electromagnetic radiation which emerges from the side surfaces of the semiconductor body and subsequently passes in the direction of the second mirror layer. In this case, that region of the second mirror layer projecting beyond the outer surface of the semiconductor body in a lateral direction need not be connected to that region of the second mirror layer arranged at the underside of the n-type contact material facing away from the n-conducting region. However, the two regions of the second mirror layer can be applied, for example, in the same production step, for example, using a mask technique.

The second mirror layer may extend at least in places below a contact region of the optoelectronic semiconductor chip, wherein the second mirror layer is electrically insulated from the contact region, and the contact region is provided for the p-side connection of the semiconductor chip from outside the semiconductor chip. By way of example, the contact region is a contact region suitable for wire contacting (also called wire bonding). A contact wire can then be fitted to the contact region, via which contact wire the optoelectronic semiconductor chip is electrically contactable on the p-side. The second mirror layer can extend below the contact region such that a reflection is also increased in this region of the semiconductor body. An electrical insulation between the contact region and the second mirror layer can be effected by the encapsulation layer sequence or a part of the encapsulation layer sequence.

The p-conducting region and the first mirror layer may be covered by a metallic encapsulation layer in places at their side surfaces, wherein the encapsulation layer sequence extends between the metallic encapsulation layer and the side surfaces. That is to say that the p-conducting region of the semiconductor body projects in places into the encapsulation layer, which acts as a planarization layer, for example, toward a carrier of the optoelectronic semiconductor chip facing away from the semiconductor body. The metallic encapsulation layer can therefore mold itself, for example, over a topography at the side of the semiconductor body facing the carrier and can planarize this. The metallic encapsulation layer is, for example, an encapsulation layer preventing diffusion of material from the mirror layers. For this purpose, the metallic encapsulation layer can be formed from or with metals such as platinum, gold, tungsten and titanium. That is to say that the metallic encapsulation layer then comprises at least one of the metals or is formed by a combination of the metals.

Furthermore, we provide a method of producing an optoelectronic semiconductor chip. An optoelectronic semiconductor chip described here, for example, can be produced by the method. That is to say that all features described for the semiconductor chip are also disclosed for the method, and vice versa.

In accordance with the method, first, a growth substrate is provided. The growth substrate can be, for example, a sapphire wafer or a silicon wafer. Afterward, the semiconductor body is applied to the growth substrate, wherein the n-conducting region faces the growth substrate and the p-conducting region faces away from the growth substrate. The semiconductor body is preferably applied epitaxially.

In a next method step, the p-conducting region is removed in places and in the process the n-conducting region below the p-conducting region is exposed in places.

In the next method step, the encapsulation layer sequence or partial layers of the encapsulation layer sequence is or are applied to exposed outer surfaces of the p-conducting region and exposed outer surfaces of the n-conducting region. This can be carried out over the whole area at the top side of the semiconductor body facing away from the growth substrate.

In the next method step, the encapsulation layer sequence is removed in places at the underside of the p-conducting region facing away from the n-conducting region and in the process the p-conducting region is exposed in places.

Finally, the first mirror layer is arranged on the exposed places of the p-conducting region, for example, by vapor deposition through a mask.

In the method, therefore, applying the encapsulation layer sequence is carried out temporally before arranging the first mirror layer. That is to say that the encapsulation layer sequence protects the p/n junction of the semiconductor body, that is to say in particular the exposed outer surfaces of the active region, already during the production method. Cleaning of the p/n junction at the mesa flanks of the semiconductor body can therefore be omitted. Furthermore, the active region, that is to say the p/n junction, is not contaminated or damaged by residues of the production method. It has been shown here that the early application of an encapsulation layer sequence remaining in the semiconductor chip and can protect the p/n junction during the entire production method leads to an optoelectronic semiconductor chip having a particularly good small-current behavior. For such a semiconductor chip, light having relatively high intensity can be generated even at particularly small current intensities of 1 μA. The optoelectronic semiconductor chip is therefore particularly well suited to applications in which the light generated by the semiconductor chip is intended to be dimmed.

Herein described optoelectronic semiconductor chips and methods of producing the optoelectronic semiconductor chips are explained in greater detail below in association with examples and associated figures.

Elements that are identical, of identical type or act identically are provided with the same reference signs in the figures. The figures and the size relationships of the elements illustrated in the figures among one another should not be regarded as to scale. Rather, individual elements may be illustrated with exaggerated size to enable better illustration and/or to afford a better understanding.

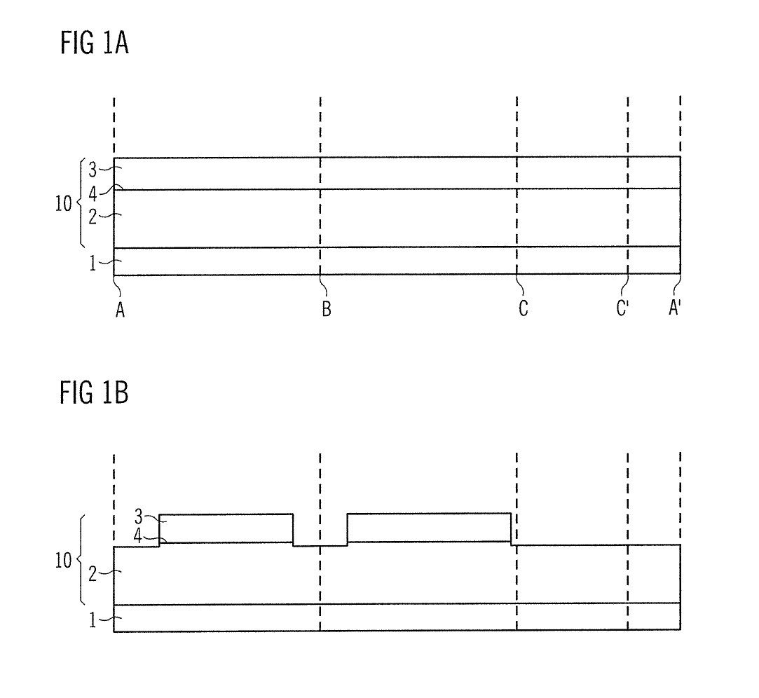

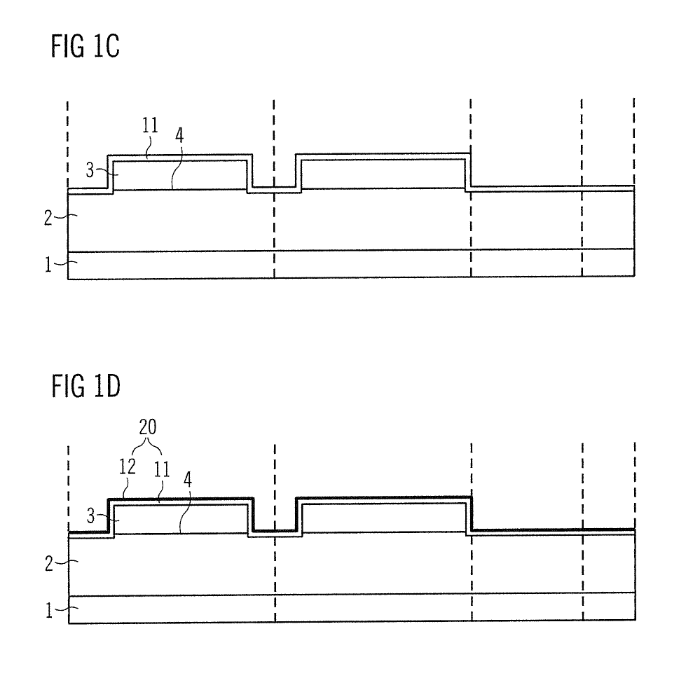

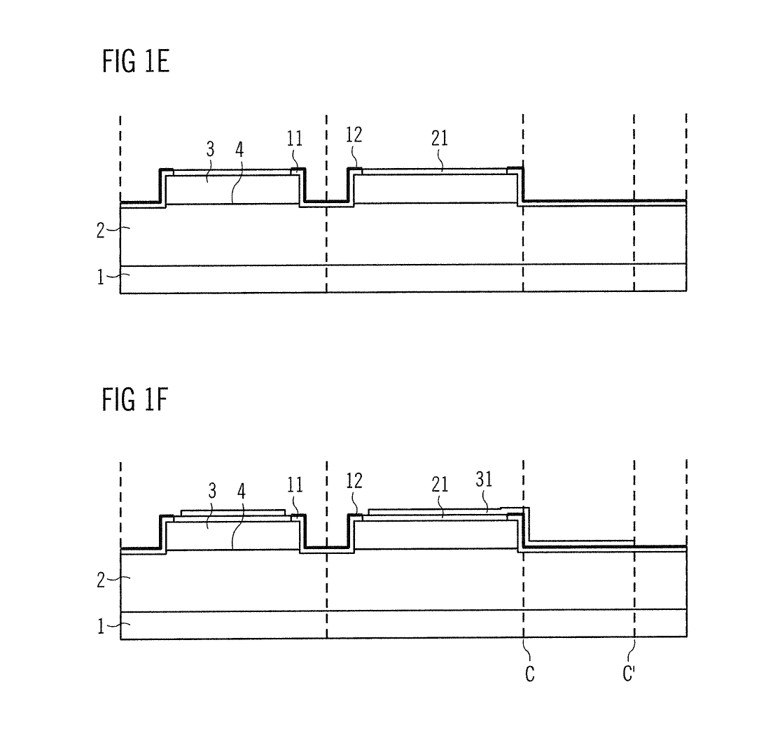

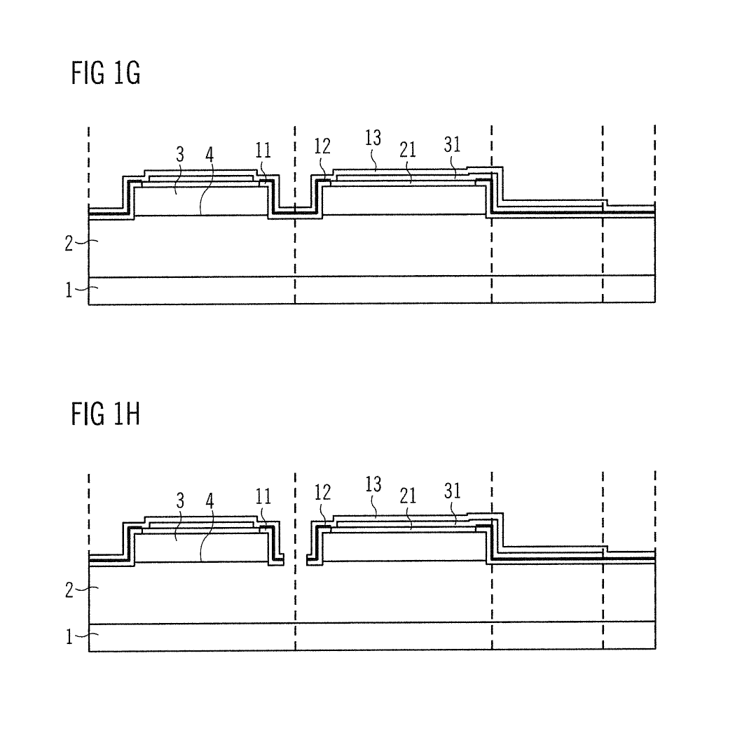

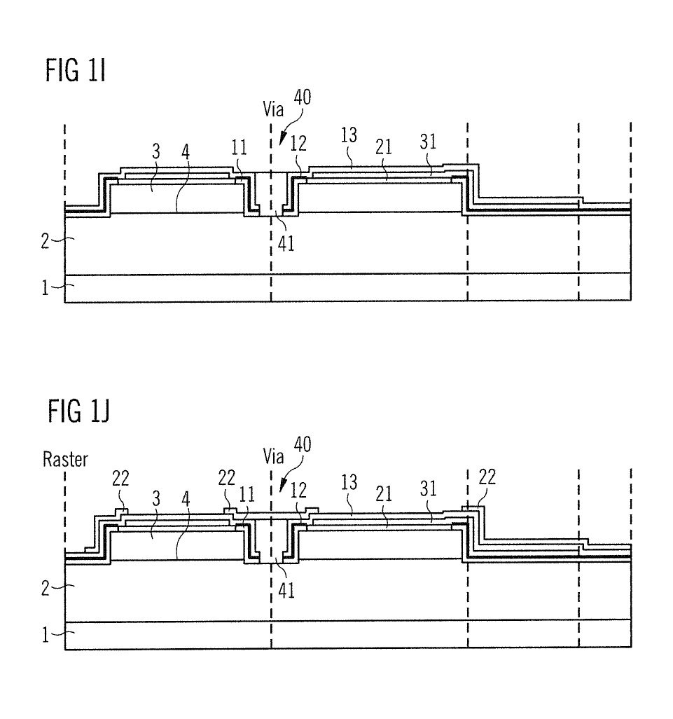

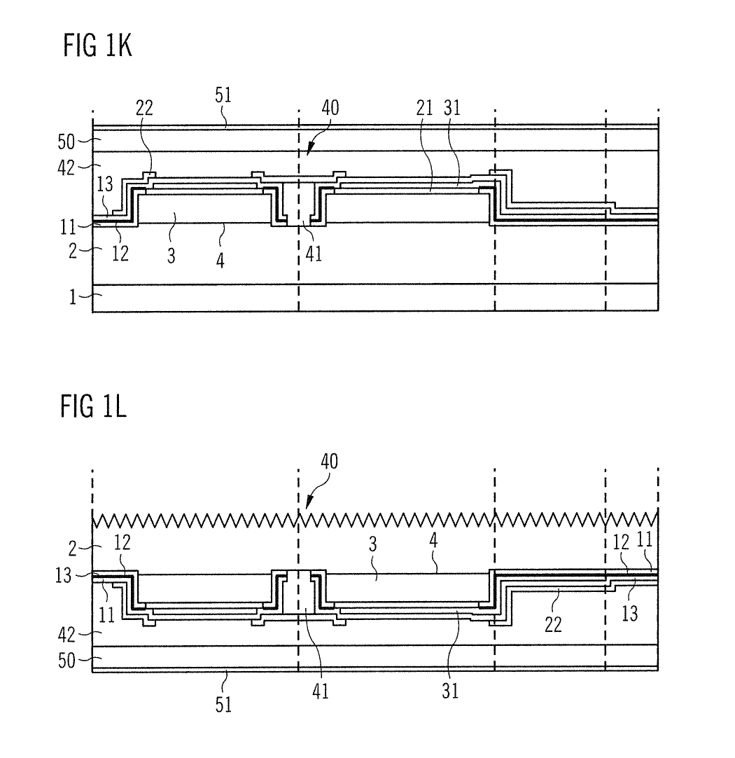

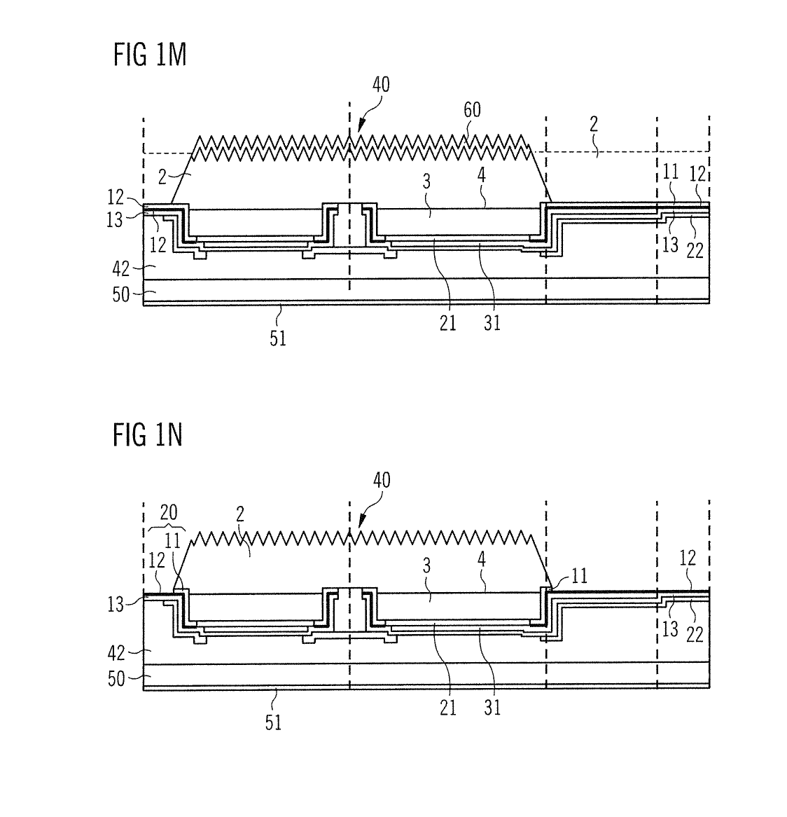

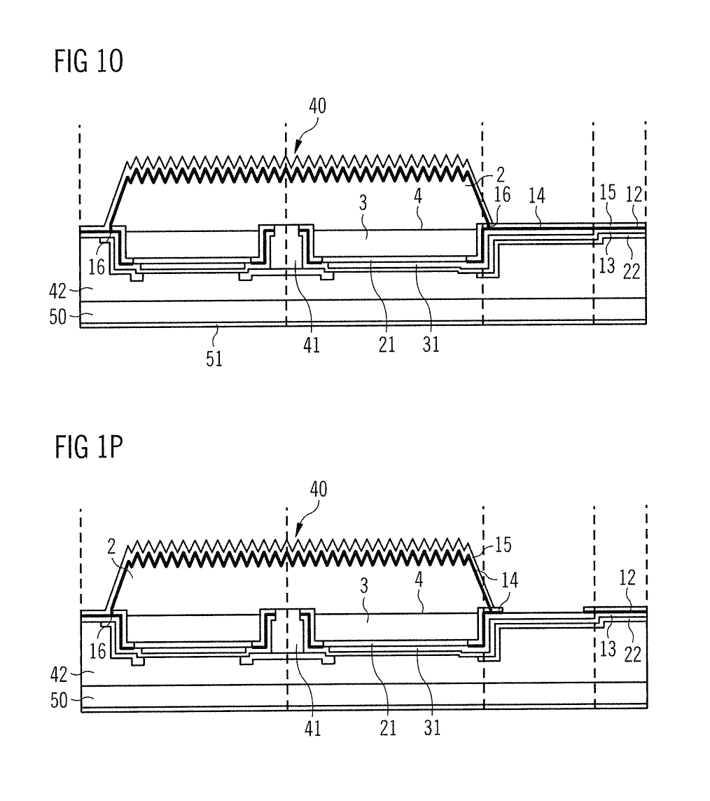

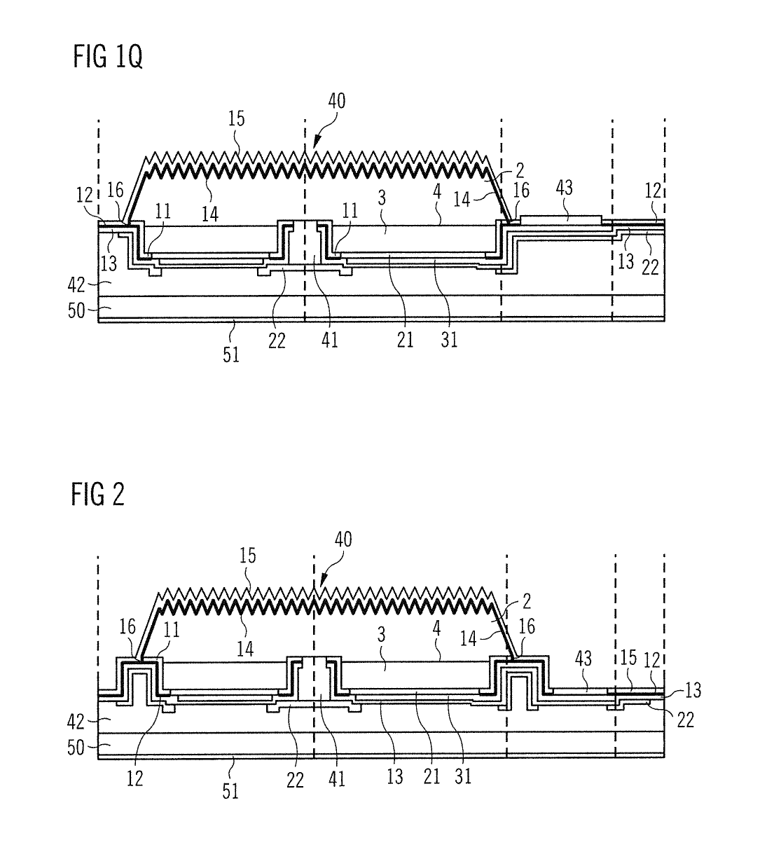

One example of a herein described method of producing an optoelectronic semiconductor chip is explained in greater detail in association with the schematic sectional illustrations in FIGS. 1A to 1Q.

FIG. 1A shows how, first, a growth substrate 1, for example, composed of sapphire is provided, onto which the semiconductor body 10 is deposited epitaxially, in particular. The semiconductor body 10 comprises the n-conducting region 2, the p-conducting region 3 and the active region 4 therebetween. In this case, the growth substrate 1 is provided as a wafer, for example, wherein the dashed lines A, A′ predefine the chip grid of the optoelectronic semiconductor chip to be produced. A plated-through hole is produced along the dashed line B during the production method. The dashed lines C, C′ represent the position of a contact region in which, for example, a bonding pad that contacts the optoelectronic semiconductor chip is formed during the production method.

The semiconductor body 10 is based, for example, on a nitride compound semiconductor material.

The subsequent method step, FIG. 1B, involves structuring the p-conducting region 3, the active region 4 and the n-conducting region 2, for example, by etching the epitaxially deposited layers of the semiconductor body 10 to form an outer surface of the semiconductor body 10 and a plated-through hole. In this case, the n-conducting region of the semiconductor body is exposed in places.

In the subsequent method step 1C, the outer surface of the semiconductor body 10 facing away from the growth substrate 1 is coated over the whole area with a first encapsulation layer 11, which is an electrically insulating layer, for example, a layer produced by a CVD method. In this case, the first encapsulation layer 11 can be an encapsulation layer sequence and comprises, for example, sublayers formed with SiO₂ and SiN. In this case, the sublayers are arranged one above another in a vertical direction, perpendicular to the lateral direction. In this case, the lateral direction lies parallel to the plane of the main extension direction of, for example, the growth substrate 1.

By way of example, the sublayers formed with SiO₂ have a thickness of 130 nm to 170 nm, in particular 150 nm. The sublayers formed with SiN can have a thickness of 10 nm to 14 nm, in particular 12 nm. In particular, encapsulation layers are formed in this way such that they are particularly impermeable also with respect to materials used during production of the ALD layers, that is to say the first encapsulation layer and the fourth encapsulation layer.

In this case, the first encapsulation layer 11 completely covers the exposed side surfaces of the p-conducting region 3 and of the active region 4 such that in particular the p/n junction of the semiconductor body is protected by the first encapsulation layer 11.

In a next method step, FIG. 1D, a second encapsulation layer 12 is applied to the top side of the first encapsulation layer 11 facing away from the growth substrate 1. The second encapsulation layer 12 is an ALD layer.

The second encapsulation layer 12, which is an ALD layer, is then produced by an ALD method, wherein the second encapsulation layer 12 is deposited at least in places, for example, using ozone as a precursor. In this case, it is possible for the entire second encapsulation layer 12 to be deposited using ozone as a precursor. Furthermore, it is possible for the second encapsulation layer 12 to comprise at least two sublayers arranged in a manner stacked one on top of another, for example, wherein at least one of the sublayers is produced by an ALD method in which ozone is used as a precursor.

We found in this case that an ALD layer for which ozone is used as a precursor has a particularly high impermeability toward moisture. The layer or sublayer which is deposited using ozone as a precursor is an Al₂O₃ layer or an SiO₂ layer, for example.

Furthermore, it is possible for the second encapsulation layer 12 to comprise a sublayer or to consist of a sublayer deposited using a precursor that is free of ozone. By way of example, water or oxygen can be used as precursor material in this case.

The second encapsulation layer 12 furthermore comprises a further sublayer deposited using a precursor comprising ozone, wherein the second sublayer is deposited directly onto the sublayer. In this case, the first sublayer can have a thickness of 5 to 10 nm, for example. The second sublayer can then have a thickness of 25 to 45 nm, for example.

The second encapsulation layer 12, too, covers the outer surfaces of the p-conducting region 3 and of the active region 4 of the semiconductor body at least indirectly. The first encapsulation layer and the second encapsulation layer jointly form the encapsulation layer sequence 20, which extends at the outer surface of the semiconductor body 10 from the active region 4 along the p-conducting region 3.

In the next method step, FIG. 1E, using a photo-technique and a lift-off technique, the encapsulation layer sequence 20 is opened and the first mirror layer 21 formed with silver, for example, is concomitantly deposited. In this way, the encapsulation layer sequence 20 extends as far as below the first mirror layer 21.

In the subsequent method step, FIG. 1F, using a further photo-technique, a p-type connecting layer 31 is deposited onto the first mirror layer 21, which extends well into the region C, C′, of the optoelectronic semiconductor chip in which a contact region 43 that contacts the p-conducting region 3 of the optoelectronic semiconductor chip is later formed.

Furthermore, it is possible for the encapsulation layer sequence 20 to be closed again above the first mirror layer 21 and the p-type connection layer 31 in a next method step (not shown). For this purpose, first and second encapsulation layers 11, 12 can be used, as described above.

In the next method step, FIG. 1G, a third encapsulation layer 13 is applied, which can be, for example, identical to the first encapsulation layer 11. In this case, the third encapsulation layer 13 extends over the entire top side of the semiconductor body 10 facing away from the growth substrate 1 and also covers the p-type connection layer 31 in this way.

In the subsequent method step, FIG. 1H, a plated-through hole 40 is produced in the region B by opening the encapsulation layers 11, 12, 13. The n-conducting region 2 is exposed in the plated-through hole 40. For this purpose, a photo-technique can be used which can subsequently also be used during introduction of the n-type contact material 41 into the plated-through hole 40.

In the next method step, FIG. 1J, the second mirror layer 22 is formed, which can be formed, for example, identically to the first mirror layer 21. In this case, the second mirror layer is arranged at the underside of the n-type contact material 41 facing away from the n-conducting region 2, wherein the encapsulation layer sequence 20 is arranged in places between the first mirror layer 21 and the second mirror layer 22. Furthermore, the lateral regions of the second mirror layer 22 project beyond the outer surface of the semiconductor body 10, in particular of the p-conducting region 3, in lateral directions.

In the next method step, FIG. 1K, first, the metallic encapsulation layer 42 is applied, which molds itself over the topography facing away from the growth substrate 1 and acts as a planarization layer. The metallic encapsulation layer 42 contains, for example, a Pt/Au/Ti layer sequence and serves as a diffusion barrier for material from the second mirror layer 22. The metallic encapsulation layer 42 can be used as a seed layer for subsequent electrolytic application of a carrier 50. In this case, the carrier 50 can be formed from copper, for example. Furthermore, it is possible for the carrier 50 to be formed from silicon or germanium or some other semiconductor material. The rear-side metallization 51 can be arranged at the side of the carrier 50 facing away from the growth substrate 1, the rear-side metallization enabling solderability of the later optoelectronic semiconductor chip.

In the next method step, FIG. 1L, the growth substrate 1 is detached and the top side of the n-conducting region 2 originally facing the growth substrate is roughened. In this case, the growth substrate 1 can be detached by a laser lift-off method, for example. The roughening is carried out by lithographic etching using KOH, for example.

In the subsequent method step, FIG. 1M, a hard mask, for example, composed of silicon dioxide is applied to the n-conducting region 2 by a photo-technique and a mesa etch is carried out which stops, for example, on the first encapsulation layer 11.

In the next method step, FIG. 1N, a dry-chemical etch of the mask layer 60 and the first encapsulation layer 11 is carried out, wherein the thickness of the mask layer 60 and that of the first encapsulation layer 11 are coupled such that a residual thickness of the first encapsulation layer 11 remains or an etch stop takes place on the second encapsulation layer 12, for example, as a result of end point detection on the Al₂O₃ sublayer of the second encapsulation layer 12.

On account of the fact that the active region 4 remains covered by the encapsulation layer sequence 20 in this case, a cleaning of the active region 4 and thus of the p/n junction of the semiconductor body 10 is obviated.

In the next method step, FIG. 10, a fourth encapsulation layer 14 is applied, which is an ALD layer formed, for example, identically to the second encapsulation layer 12. In this case, contact points 16 form between the second and fourth encapsulation layers, in which these two encapsulation layers directly contact one another.

In this way, it is possible for a large region of the semiconductor body 10 to be enclosed with encapsulation layers 12, 14 which are ALD layers.

A fifth encapsulation layer 15 is subsequently applied, which is a silicon dioxide layer, for example. The latter constitutes a terminating passivation of the semiconductor body.

In the method step in FIG. 1P, the p-type connection layer 31 is exposed and, in the method step in FIG. 1Q, the contact region 43 is deposited onto the p-type connection layer 31, the contact region being formed with a wire-contactable material, for example.

In contrast to the example in FIG. 1Q, FIG. 2 shows an optoelectronic semiconductor chip in which the second mirror layer 21 is not drawn below the contact region 43, but rather has a cutout there. In this case, it is also possible for the metallic encapsulation layer 42 to be made thinner than in the example in FIG. 1Q.

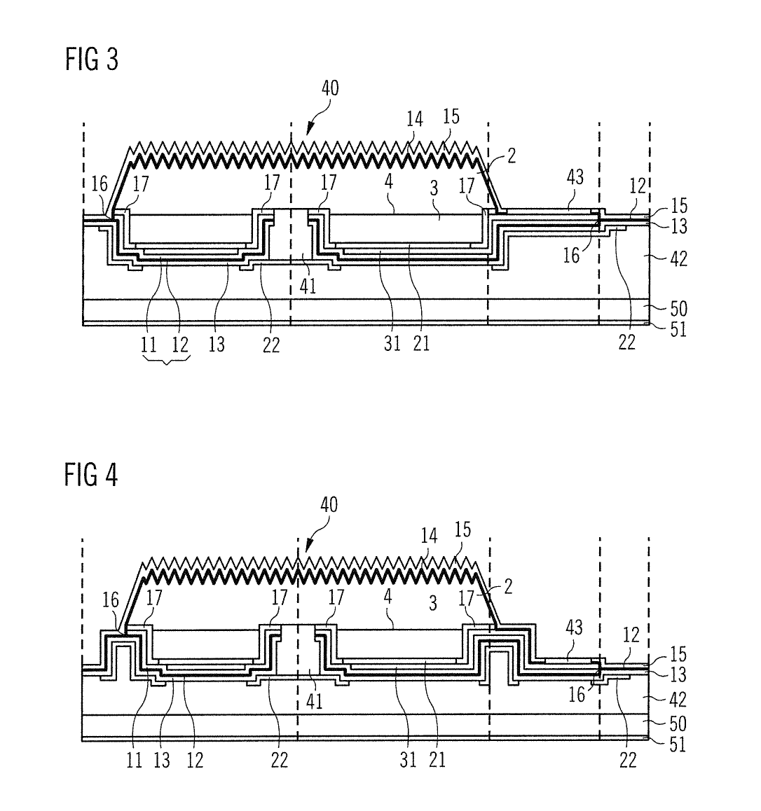

In the example in FIG. 3, the encapsulation layer sequence 20 extends along the underside of the first mirror layer 21 facing away from the p-conducting region 3, wherein the encapsulation layer sequence 20 completely covers the first mirror layer 21 without being in direct contact therewith.

In this example, apart from the at least one plated-through hole 40, the semiconductor body 10 is completely enclosed by the second and fourth encapsulation layers, which are ALD layers.

The example in FIG. 4 constitutes a combination of the examples in FIGS. 2 and 3 in which the second mirror layer 22 is not led below the contact region 43 and the semiconductor body 10, apart from the regions of the plated-through hole 40, is completely encapsulated by the ALD layers 12, 14.

Our chips and methods are not restricted to the examples by the description on the basis of the examples. Rather, this disclosure encompasses any novel feature and also any combination of features, which in particular includes any combination of features in the appended claims, even if the feature or combination itself is not explicitly specified in the claims or examples.

1-12. (canceled)

13. An optoelectronic semiconductor chip comprising:
a semiconductor body comprising an n-conducting region, an active region that generates electromagnetic radiation, and a p-conducting region;
a first mirror layer that reflects the electromagnetic radiation; and
an encapsulation layer sequence formed with an electrically insulating material, wherein
the first mirror layer is arranged at an underside of the p-conducting region;
the active region is arranged at a side of the p-conducting region facing away from the first mirror layer;
the n-conducting region is arranged at a side of the active region facing away from the p-conducting region;
the encapsulation layer sequence covers the semiconductor body at the outer surface thereof in places;
the encapsulation layer sequence extends at the outer surface of the semiconductor body from the active region along the p-conducting region as far as below the first mirror layer; and
the encapsulation layer sequence comprises at least one encapsulation layer which is an ALD layer or consists of an ALD layer.

14. The optoelectronic semiconductor chip according to claim 13, wherein the encapsulation layer sequence extends along an underside of the first mirror layer facing away from the p-conducting region, and the encapsulation layer sequence covers the first mirror layer at least in places.

15. The optoelectronic semiconductor chip according to claim 13, wherein the encapsulation layer sequence extends along an underside of the first mirror layer facing away from the p-conducting region, and the encapsulation layer sequence completely covers the first mirror layer.

16. The optoelectronic semiconductor chip according to claim 13, further comprising at least one further encapsulation layer which is an ALD layer, wherein the further encapsulation layer completely covers the outer surface of the semiconductor body at least at the n-conducting region.

17. The optoelectronic semiconductor chip according to claim 13, further comprising at least one plated-through hole extending through the p-conducting region and the active region well into the n-conducting region, wherein
the plated-through hole comprises an n-type contact material via which the n-conducting region is electrically contactable, and
the semiconductor body, apart from the at least one plated-through hole, is completely enclosed by the encapsulation layers which are ALD layers.

18. The optoelectronic semiconductor chip according to claim 17, wherein the encapsulation layer sequence directly adjoins the n-type contact material in places.

19. The optoelectronic semiconductor chip according to claim 13, wherein the encapsulation layer and the further encapsulation layer directly contact one another at at least one contact point.

20. The optoelectronic semiconductor chip according to claim 13, further comprising a second mirror layer arranged at an underside of the n-type contact material facing away from the n-conducting region, wherein the encapsulation layer sequence is arranged in places between the first mirror layer and the second mirror layer.

21. The optoelectronic semiconductor chip according to claim 20, wherein the second mirror layer projects beyond the outer surface of the semiconductor body in a lateral direction.

22. The optoelectronic semiconductor chip according to claim 20, wherein the second mirror layer extends below a contact region at least in places, and the second mirror layer is electrically insulated from the contact region and the contact region is provided for the p-side connection of the semiconductor chip from outside the semiconductor chip.

23. The optoelectronic semiconductor chip according to claim 13, wherein the p-conducting region and the first mirror layer are covered by a metallic encapsulation layer in places at their side surfaces, and the encapsulation layer sequence extends between the metallic encapsulation layer and the side surfaces.

24. A method of producing an optoelectronic semiconductor chip according to claim 13 comprising:
providing a growth substrate;
applying the semiconductor body to the growth substrate, wherein the n-conducting region faces the growth substrate and the p-conducting region faces away from the growth substrate;
removing the p-conducting region and the active region in places and exposing the n-conducting region in places;
applying the encapsulation layer sequence on exposed outer surfaces of the p-conducting region, of the active region and of the n-conducting region;
removing the encapsulation layer sequence in places at an underside of the p-conducting region facing away from the n-conducting region, and exposing the p-conducting region in places; and
arranging the first mirror layer on the exposed places of the p-conducting region, wherein applying the encapsulation layer sequence is carried out temporally before arranging the first mirror layer.

25. An optoelectronic semiconductor chip comprising:
a semiconductor body comprising an n-conducting region, an active region that generates electromagnetic radiation, and a p-conducting region;
a first mirror layer that reflects the electromagnetic radiation; and
an encapsulation layer sequence formed with an electrically insulating material, wherein
the first mirror layer is arranged at an underside of the p-conducting region;
the active region is arranged at a side of the p-conducting region facing away from the first mirror layer;
the n-conducting region is arranged at a side of the active region facing away from the p-conducting region;
the encapsulation layer sequence covers the semiconductor body at outer surface thereof in places;
the encapsulation layer sequence extends at the outer surface of the semiconductor body from the active region along the p-conducting region as far as below the first mirror layer;
the encapsulation layer sequence comprises at least one encapsulation layer which is an ALD layer or consists of an ALD layer;
the encapsulation layer sequence is situated partly in the n-conducting region at the outer surface of the semiconductor body and extends along the underside of the first mirror layer facing away from the p-conducting region; and
the encapsulation layer sequence covers the first mirror layer at least in places.

26. The optoelectronic semiconductor chip according to claim 13, wherein the encapsulation layer sequence is situated partly in the n-conducting region at the outer surface of the semiconductor body.

27. A method of producing an optoelectronic semiconductor chip comprising:
providing a growth substrate;
applying a semiconductor body to the growth substrate, wherein a n-conducting region of the semiconductor body faces the growth substrate and a p-conducting region of the semiconductor body faces away from the growth substrate;
removing the p-conducting region and an active region of the semiconductor body in places and exposing the n-conducting region in places;
applying an encapsulation layer sequence on exposed outer surfaces of the p-conducting region, of the active region and of the n-conducting region;
removing the encapsulation layer sequence in places at an underside of the p-conducting region facing away from the n-conducting region, and in the process exposing the p-conducting region in places;
arranging a first mirror layer on the exposed places of the p-conducting region, wherein
applying the encapsulation layer sequence is carried out temporally before arranging the first mirror layer, and
the encapsulation layer sequence comprises at least one encapsulation layer which is an ALD layer or consists of an ALD layer and which is deposited at least in places using ozone as a precursor.
